(19) United States
(12) Patent Application Publication
(10) Pub. No.: US 2002/0164889 A1
(43) Pub. Date: Nov. 7, 2002

(54) Method for improving adhesion of low k materials with adjacent layer

(76) Inventors: Cheng-Yuan Tsai, Yun-Lin (TW); Anseime Chen, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/847,107

(22) Filed: May 2, 2001

(51) Int. Cl. H01L 21/31; H01L 21/4763

(52) U.S. Cl. 438/763; 438/624; 438/623

(57) ABSTRACT

The present invention provides a method for improving adhesion of low k materials with adjacent Layer. The method at least includes the following steps. First of all, the semiconductor device is provided, and a cap layer is formed on the semiconductor structure. Then, an adhesion promoter layer is formed on the cap layer by spin coating, and a polymer low dielectric constant layer is formed on the adhesion promoter layer. Next, an HMDS (Hexamethyldisilazane) film is deposited on the low dielectric constant layer, the HMDS film can provide both of inorganic and organic bonds. Finally, an etching stop layer or hardmask inorganic layer is formed on the HMDS film.

### BACKGROUND OF THE INVENTION

1. Field of the Invention

The invention relates to a method for improving adhesion of low k materials with an adjacent layer and more particularly to a method for strengthening the adhesion ability of a low dielectric constant layer by using HMDS (Hexamethyldisilazane) acted as hydrophobic treatment.

1. Description of the Prior Art

It is the nature of semiconductor physics that as the feature sizes are scaled down, the performance of internal devices in integrated circuits improves in a compounded fashion. That is, the device speed as well as the functional capability improves. The overall circuit speed, however, becomes more dependent upon the propagation speed of the signals along the interconnects that connect the various devices together. With the advent of very and ultra large scale integration (VLSI and ULSI) circuits, it has therefore become even more important that the metal conductors that form the interconnections between devices as well as between circuits in the semiconductor have low resistivities for high signal propagation. Copper is often preferred for its low resistivities, as well as for resistance to electromigration and stress voiding properties.

On the other hand, considerable attention has focused on the replacement of silicon dioxide with new materials, having a lower dielectric constant, since both capacitive delays and power consumption depend on the dielectric constant of the insulator. Accordingly, circuit performance enhancement has been sought by combining the copper conductors with low dielectric constant layer (k less than approximately 4).

An example of dual damascene process using a low k dielectric material is depicted in FIG. 1. A conductor 21 having a low resistivity, such as copper, is provided in an interconnect layer 20. Then, a cap layer 22 is formed on the interconnect layer 20. The first adhesion promoter 24 is formed on the cap layer 22 by spin-on coating. The first low k dielectric constant layer 26 is then formed on the first adhesion promoter 24 by spin-on method. Next, an etching stop layer 28 is formed on the first low k dielectric constant layer 26. Then, a second adhesion promoter 30 is formed on the etching stop layer 28 by spin coating. And, the second low k dielectric constant layer 32 is then formed on the second adhesion promoter 30 by spin-on method. Finally, an hardmask layer 34 is deposited on the second low k dielectric constant layer 32 by the method of plasma enhanced chemical vapor deposition (PECVD) for incoming steps.

The adhesion between inorganic and organic material are actually of great concerns. Typically an inter-layer dielectric constant layer, i.e., adhesion promoter, both containing organic and inorganic group components are inserted between inorganic and organic layer. Currently using spin coat type for adhesion promoter has been extensively applied for days. However, for Cu dual damascene process, the top surface of low k polymer layer are adjacent to etch stop layer or hardmask layer and without adhesion promoter having been applied. Actually, poor adhesion at interface of etching stop layer and hardmask layer has been found due to no adhesion promoter being applied. This would result in a very poor adhesion between polymer and inorganic layer. One of primary reasons why adhesion promoter could not be used on top of organic layer is due to the wettability concerns which causes an issue of poor coating using spin-on method. Conceptually the adhesion promoter is acted as a treatment of hydrophobic which is changing a hydrophilic surface of under-layer to hydrophobic, followed by organic film coating. In this way, adhesion promoter is formed by spin-on coating which could be influenced by surface state of under layer, such as surface topography, wettability and previous step defect, etc.

For the forgoing reasons, there is a need for a method of for improving adhesion of low k materials with adjacent layer. This invention applies a vapor deposition type HMDS (Hexamethyldisilazane) on top of organic layer. It would obtain better thickness uniformity than conventional spin coat type due to better conformality.

### SUMMARY OF THE INVENTION

In accordance with the present invention, a method for improving adhesion of low k materials with adjacent layer is provided that adhesion ability in conventional process substantially can be increased.

One of the objectives of the present invention is to provide a method for improving adhesion of low k materials with adjacent layer. Formation of an HMDS (Hexamethyldisilazane) film applies a vapor deposition type to obtain better comformality on the low dielectric constant materials, compared to that of spin-on process.

Another one of the objectives of the present invention is to provide a method for improving adhesion of low k materials with adjacent layer. Formation of an HMDS (Hexamethyldisilazane) film comprises inorganic and organic bonds to adjacent low dielectric constant materials.

In order to achieve the above objectives, the present invention provides a method for improving adhesion of low k materials with adjacent layer. The method at least includes the following steps. First of all, a semiconductor device is provided, and a cap layer is formed on the semiconductor structure. Then, an adhesion promoter layer is formed on the cap layer by spin coating, and a low dielectric constant layer is formed on the adhesion promoter layer. Next, an HMDS film is deposited on the low dielectric constant layer, wherein the HMDS film can provide inorganic and organic bonds. Following, an etching stop layer is formed on the HMDS film.

### BRIEF DESCRIPTION OF THE DRAWINGS

The foregoing aspects and many of the attendant advantages of this invention will become more readily appreciated as the same becomes better understood by referring to the following detailed description, when taken in conjunction with the accompanying drawings, wherein:

FIG. 1 is a cross-sectional schematic diagram illustrating low dielectric constant layer applied on the dual damascene structure in accordance with the prior art; and

FIGS. 2A-2E are cross-sectional schematic diagrams illustrating low dielectric constant applied on the dual damascene structure in accordance with the present invention.

### DESCRIPTION OF THE PREFERRED EMBODIMENT

The semiconductor devices of the present invention are applicable to a broad range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarity of illustration and should not be interpreted in a limiting sense. Accordingly, these regions will have dimensions, including length, width and depth, when fabricated in an actual device.

In the present invention, a method for forming an HMDS film from a low dielectric constant layer in the semiconductor structure comprises providing the semiconductor structure and a low dielectric constant layer thereon. Next, the low dielectric constant layer is deposited and then the HMDS film is formed on the low dielectric constant layer. The HMDS film can provide inorganic and organic bonds bonding between the low dielectric constant polymer layer and the other inorganic type layer.

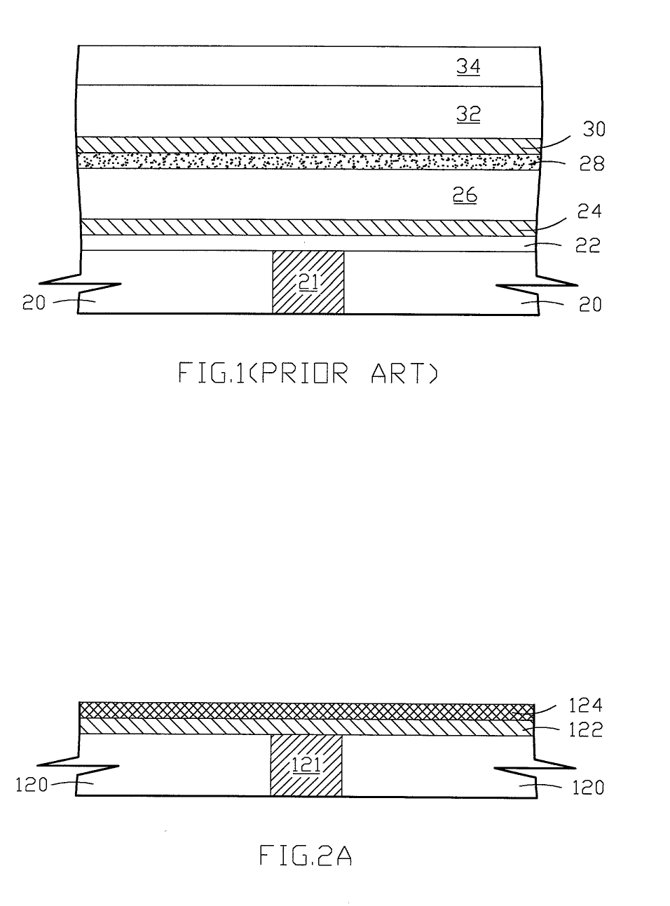

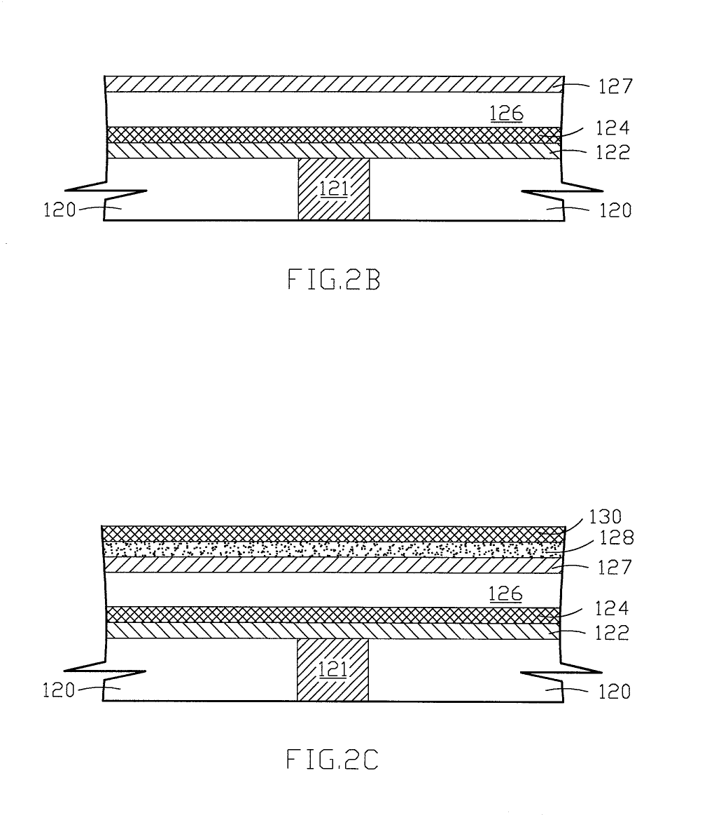

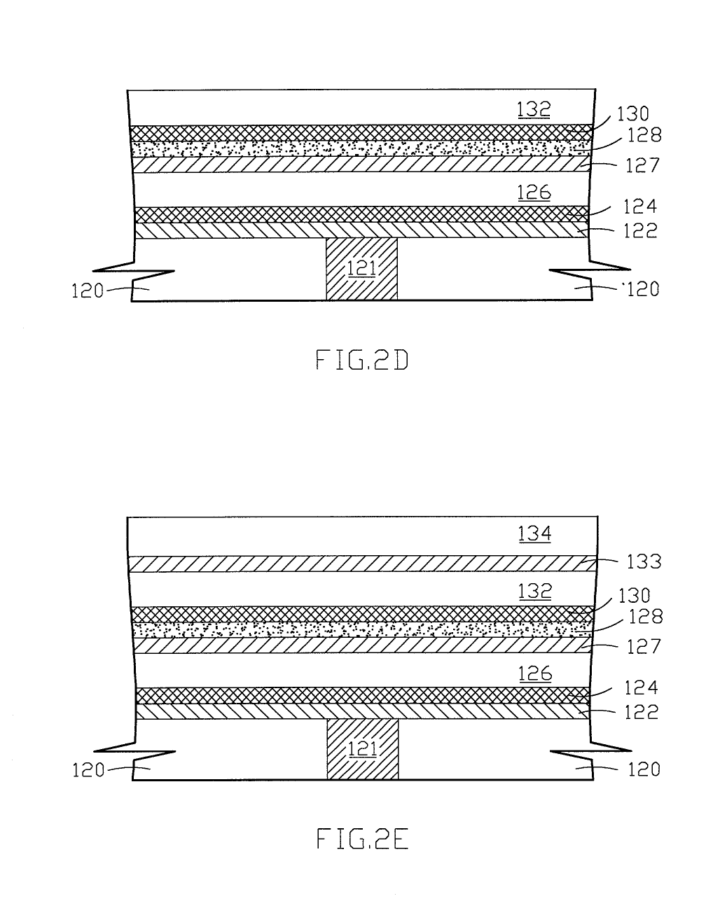

The embodiment of the present invention is depicted in FIGS. 2A-2E, which show a cross-section of an interconnect portion of a semiconductor device, such as a semiconductor structure in the dual damascene process.

Referring to FIG. 2A, a conductor 121 having a low resistivity, such as copper, is provided in an interconnect layer 120. Then, a cap layer 122 is formed on the interconnect layer 120. The cap layer 122 can protect conductor 121 from being harmed and provide a resistance of copper outward diffusion. Consequently, the cap layer 122 is acted as a passivation layer. Then, a first adhesion promoter film 124 is formed on the cap layer 122 by spin coating. The first adhesion promoter film 124 is formed with a thickness between 80 angstroms and 150 angstroms. In the embodiment, thickness of this layer is preferable less than 100 angstroms. The first adhesion promoter film 124 can increase adhesion between the cap layer 122 and the first low k dielectric constant layer of polymer material 126. The first adhesion promoter film 124 is formed with a dielectric constant of between 4 and 6.

Referring to FIG. 2B, the first polymer low k dielectric constant layer 126 is then formed on the first adhesion promoter film 124 by using spin-on method. The first low k dielectric constant layer 126 may be made of a polymer material, such as SiLK™. This material is considered to be a low k dielectric materials since its dielectric constant is proven less than about 3. Then, the first HMDS film 127 is formed over the first dielectric constant layer 126 by vapor deposition method. The first HMDS film 127 is formed at temperature of between 60° C. and 150°C. In the embodiment, temperature of this layer is preferable 80° C. The first HMDS film 127 with a thickness between 10 angstroms and 100 angstroms. In the embodiment, thickness of this layer is preferable 20 angstroms.

The first HMDS structure is:

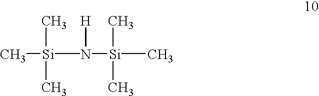

On the other hand, the first HMDS film 127 can provide both containing organic and inorganic groups bonding to connect organic layer (i.e. dielectric constant layer 126) and inorganic layer (irecapping layer 122, etching stop layer 128). The first HMDS film 127 has organic C—H bonds and inorganic N—H, Si—C bonds to improve adhesion of low k materials with adjacent layer. Also, the first HMDS film 127 has very thin layer without much impact on etch process window.

Referring to FIG. 2C, an etching stop layer 128 is formed on the first HMDS film 127. The etching stop layer 128 either comprises silicon nitride (SiN) or silicon carbon (SiC) . The etching stop layer 128 is formed over the first HMDS film 127 by CVD method. The etching stop layer 128 can provide different selective etching ratio on the first HMDS film 127. The first HMDS film 127 can change a hydrophilic surface of under layer to hydrophobic. Then, a second adhesion promoter film 130 is formed on the etching stop layer 128 by convertional spin-on coating. A second adhesion promoter film 130 is formed with a thickness between 80 angstroms and 150 angstroms. In the embodiment, thickness of this layer is preferable less than 100 angstroms. The second adhesion promoter film 130 can increase adhesion between the etching stop layer 128 and second low k dielectric constant layer 132. The second adhesion promoter film 130 is formed with a dielectric constant of between 4 and 6.

Referring to FIG. 2D, a second polymer low k dielectric constant layer 132 is then formed on the second adhesion promoter film 130 by CVD method. The second low k dielectric constant layer 132 may be made of a polymer material, such as SiLK™.

Referring to FIG. 2E, the second HMDS film 133 is formed over the second low k dielectric constant layer 132 by vapor deposition method. The second HMDS film 133 is formed at temperature of between 60° C. and 150° C. In the embodiment, temperature of this layer is preferable 80° C. The second HMDS film 133 with a thickness between 10 angstroms and 100 angstroms. In the embodiment, thickness of this layer is preferable 20 angstroms.

The second HMDS structure is:

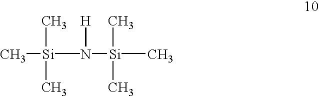

On the other hand, the second HMDS film 133 can provide both containing organic and inorganic groups bonding to connect organic layer (i.e. dielectric constant layer 132) and inorganic layer (i.e. hardmask layer 134) . The second HMDS film 133 has organic C—H bonds and inorganic N—H, Si—C bonds to adhesion of low K materials with adjacent layer. Also, the second HMDS film 133 has very thin layer without much impact on etch process window. The second HMDS film 133 can change a hydrophilic surface of under layer to hydrophobic. Then, an hardmask layer 134 is deposited on the second HMDS film 133 by the method of plasma enhanced chemical vapor deposition (PECVD) for incoming steps.

One of the objectives of the present invention is to provide a better method to adhere inorganic bonds and organic bonds of the low K materials. The formation of the HMDS film can replace the spin on method, so the present invention can be applied on the replacement of all the spin on method for the inorganic layer and organic layer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for improving adhesion of low k materials with adjacent layer in a semiconductor structure of the type having a cap layer, an adhesion promoter layer, a low dielectric constant layer and an etching stop layer, wherein the improvement comprising:
depositing an adhesion film on said low dielectric constant layer, said adhesion film both have inorganic and organic bonds.

2. The method according to claim 1, wherein said low dielectric constant layer is a polymer layer using spin-on coating.

3. The method according to claim 1, wherein said adhesion film is formed at a temperature between 60° C. and 150° C.

4. The method according to claim 3, wherein said adhesion film is treated to hydrophobic surface.

5. The method according to claim 4, wherein said adhesion film is deposited by vapor deposition.

6. The method according to claim 5, wherein said adhesion film is formed with a thickness of between 10 angstroms and 100 angstroms.

7. The method according to claim 6, wherein said adhesion film is Hexamethyldisilazane film.

8. A method for improving adhesion of low k materials with adjacent layer in a semiconductor structure, said method comprising:
providing a semiconductor structure;
forming a cap layer on said semiconductor structure;
forming an adhesion promoter layer on said cap layer;
forming a low dielectric constant layer on said adhesion promoter layer;
depositing a HMDS film on said low dielectric constant layer, said HMDS film both have inorganic and organic bonds; and
forming an etching stop layer on said HMDS film.

9. The method according to claim 8, wherein said low dielectric constant layer is a polymer layer using spin-on coating.

10. The method according to claim 9, wherein said HMDS film is formed at a temperature between 60° C. and 150° C.

11. The method according to claim 10, wherein said HMDS film is treated to hydrophobic surface.

12. The method according to claim 11, wherein said HMDS film is deposited by vapor deposition.

13. The method according to claim 12, wherein said HMDS film is formed with a thickness of between 10 angstroms and 100 angstroms.

14. A method for improving adhesion of low k materials with adjacent layer in a semiconductor structure, said method comprising:
providing a semiconductor structure;
forming a cap layer on said semiconductor structure;
forming a first adhesion promoter layer on said cap layer;
forming a first polymer layer on said first adhesion promoter layer;
depositing a first HMDS film on said polymer layer, said first HMDS film has inorganic and organic bonds;
forming an etching stop layer on said first HMDS film;
forming a second adhesion promoter layer on said etching stop layer;
forming a second polymer layer on said second adhesion promoter layer;
depositing a second HMDS film on said second polymer layer, said second HMDS film both have inorganic and organic bonds; and
forming an hardmask layer on said second HMDS film.

15. The method according to claim 14, wherein said adhesion film is formed at a temperature between 60° C. and 150° C.

16. The method according to claim 15, wherein said adhesion film is treated to hydrophobic surface.

17. The method according to claim 16, wherein said HMDS film is deposited by vapor deposition.

18. The method according to claim 17, wherein said HMDS film is formed with a thickness of between 10 angstroms and 100 angstroms.
